(19) United States
(12) Patent Application Publication
(10) Pub. No.: US 2024/0097673 A1
(43) Pub. Date: Mar. 21, 2024

(54) A PASSIVE TIMING CIRCUIT FOR OPTOCOUPLED RELAYS

(71) Applicant: Geoffrey BOND, Melbourne (AU)

(72) Inventor: Geoffrey BOND, Melbourne (AU)

(21) Appl. No.: 18/255,440

(22) PCT Filed: Dec. 2, 2021
(86) PCT No.: PCT/AU2021/051435

§ 371 Date: Jun. 1, 2023

(30) Foreign Application Priority Data
Dec. 4, 2020 (AU) 2020904484

(51) Int. Cl. H03K 17/28; H01H 47/18; H03K 17/08; H03K 17/78

(52) U.S. Cl. CPC H03K 17/28; H01H 47/18; H03K 17/08; H03K 17/78; H03K 2017/515

(57) ABSTRACT

A passive timing circuit for optocoupled relay has a rail having an output for an input terminal of the optocoupled relay. The circuit also has a capacitive network between the rail and ground. The capacitance of the capacitive network can be configured according to a timing period and the circuit does not require a voltage source other than that applied by the input terminal which, over the time period, increases voltage of the rail until the relay switches.

### FIELD OF THE INVENTION

This invention relates generally to electrical timing circuits and, more particularly, to a passive timing circuit for optocoupled relays.

### BACKGROUND OF THE INVENTION

Electrical timing circuits of various configurations exist for a variety of timers, delay, pulse generation, and oscillator applications, including active timing circuits using 555 timer ICs.

The present invention seeks to provide a timing circuit, which will overcome or substantially ameliorate at least some of the deficiencies of the prior art, or to at least provide an alternative.

It is to be understood that, if any prior art information is referred to herein, such reference does not constitute an admission that the information forms part of the common general knowledge in the art, in Australia or any other country.

### SUMMARY OF THE DISCLOSURE

There is provided herein a passive timing circuit which is robust, requiring no external power source and is less complicated than conventional timing circuits such as those using 555 timer ICs. The circuit also uses very small amounts of current in order to operate (maximum initial current consumption for a module with the present invented circuit is typically 26 mA and the quiescent current draw is 1.2 mA.)

The present timing circuit is specifically suitable for optocoupled relay modules. The circuit comprises a rail having an output for an input terminal of the optocoupled relay and has a capacitive network between the rail and ground. The capacitance values of the capacitive network can be configured according to a desired timing period. Similarly, the resistance values of the circuit can be configured according to a desired timing period.

The circuit is without a voltage source wherein it was discovered that a low voltage applied by optocoupled relay at the input terminal thereof gradually causes the voltage of the rail to rise until such time that the relay switches.

The circuit may further comprise a reset switch which pulls the rail to ground to reset the timing operation thereof.

The timing circuit was found to time approximately ten minutes maximum for a maximum of 10,000 μF of capacitance of the capacitive network and the resistor impedance is a maximum of 56K ohms in order to achieve a maximum time of 10.5 minutes.

Other aspects of the invention are also disclosed.

### BRIEF DESCRIPTION OF THE DRAWINGS

Notwithstanding any other forms which may fall within the scope of the present invention, preferred embodiments of the disclosure will now be described, by way of example only, with reference to the accompanying drawings in which:

FIG. 1 shows a passive timing circuit for an optocoupled relay in accordance with an embodiment.

### DESCRIPTION OF EMBODIMENTS

A passive timing circuit 100 for optocoupled relay comprises a rail 101 having an output 102 for an input terminal of the optocoupled relay 108.

The circuit 100 further comprises a capacitive network 103 between the rail 101 and ground 104.

The capacitance of the capacitive network 103 is configured according to a timing period.

The circuit 100 is without a voltage source other than leakage voltage applied by the input terminal of the optocoupled relay 108. As such, over the time period, the voltage applied by the input terminal of the optocoupled relay increases voltage of the rail 101 until the optocoupled relay 108 switches.

Normally open or normally closed contacts of the optocoupled relay 108 may be used depending on the application thereof.

The circuit 100 may further comprise a reset switch 105 which pulls the rail 101 to ground 104. The reset switch 105 may comprise a manually operated switch that has a pushbutton or the like which may be manually operated to reset the circuit 100 to recommence timing. In alternative embodiments, the reset switch 105 may comprise a relay.

The capacitive network 103 may comprise a plurality of capacitors 107 in parallel.

Trial and experimentation found that the voltage applied by the input terminal of the optocoupled relay causes the circuit 100 to time a period of approximately ten minutes for approximately 10,000 μF of capacitance of the capacitive network 103.

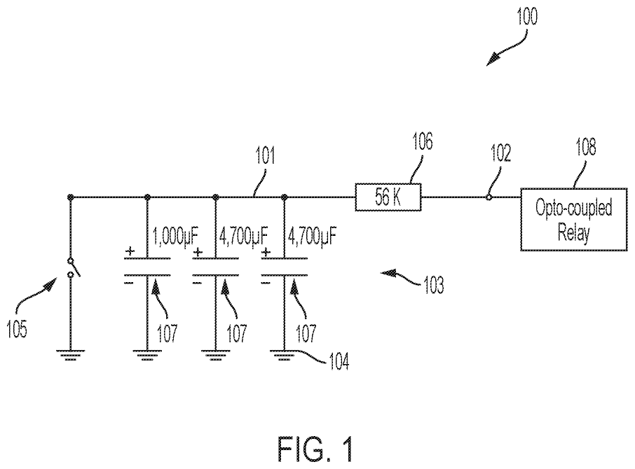

For example, the capacitance of the capacitors 107 shown in FIG. 1 is approximately 10,400 μF, thereby providing a timing period of approximately ten and a half minutes (maximum).

The circuit 100 may comprise a current limiting resistor 106 between the resistive network 103 and the output 102. The resistor 106 may comprise a resistance of maximum 56 kΩ and have a power rating of approximately 0.25 W. The chosen resistance of the current limiting resistor 106 may affect the timing of the circuit 100. In this regard, in embodiments, the current limiting resistor 106 may be a variable resistor, such as a tunable potentiometer, which may be adjusted during use to adjust the timing of the circuit 100.

Utilisation of the circuit 100 for timing a time period may comprise applying the circuit 100 to an input of an optocoupled relay controlling a further circuit. The capacitance of the capacitive network in conjunction with the resistor may be adjusted to control the timing period wherein, for example, a capacitance of approximately 10,000 μF and a resistor of 56 K ohm provides a time period of approximately ten minutes.

No other voltage source is applied to the circuit other than that which leaks from the input terminal of the optocoupled relay 108 which causes the voltage of the rail 101 to rise steadily until the optocoupled relay switches.

The method may further comprise operating the reset switch 105 to pull the rail 101 to ground to reset the timing circuit 100.

The foregoing description, for purposes of explanation, used specific nomenclature to provide a thorough understanding of the invention. However, it will be apparent to one skilled in the art that specific details are not required in order to practise the invention. Thus, the foregoing descriptions of specific embodiments of the invention are presented for purposes of illustration and description. They are not intended to be exhaustive or to limit the invention to the precise forms disclosed as obviously many modifications and variations are possible in view of the above teachings. The embodiments were chosen and described in order to best explain the principles of the invention and its practical applications, thereby enabling others skilled in the art to best utilize the invention and various embodiments with various modifications as are suited to the particular use contemplated. It is intended that the following claims and their equivalents define the scope of the invention.

The term “maximum” or similar as used herein should be construed as being the highest values to achieve the most time produced as per limitations of the circuit.

1. A passive timing circuit for optocoupled relay, the circuit comprising a rail having an output for an input terminal of the optocoupled relay and a capacitive network between the rail and ground, the capacitance of the capacitive network configured according to a timing period wherein the circuit is without a voltage source other than that applied by the input terminal which, over the time period, increases voltage of the rail until the relay switches.

2. The passive timing circuit as claimed in claim 1, further comprising a reset switch which pulls the rail to ground.

3. The passive timing circuit as claimed in claim 2, wherein the reset switch comprises a manually operated switch.

4. The passive timing circuit as claimed in claim 1, wherein the capacitive network comprises a plurality of capacitors in parallel.

5. The passive timing circuit as claimed in claim 1, wherein the capacitive network comprises a capacitance of approximately 10,400 μF.

6. The passive timing circuit as claimed in claim 5, wherein the time period is between 1 and 11 minutes.

7. The passive timing circuit as claimed in claim 1, further comprising a current limiting resistor between the capacitive network and the output.

8. The passive timing circuit as claimed in claim 7, wherein the resistor comprises a resistance of approximately 56 kΩ.

9. The passive timing circuit as claimed in claim 8, wherein the resistor comprises variable resistor so that the timing of the circuit can be dynamically adjusted accordingly.

10. The passive timing circuit as claimed in claim 7, wherein the resistor has a power rating of approximately 0.25 W.

11. A method of switching an optocoupled relay, the method comprising applying a circuit as claimed in claim 1 to an input terminal of the optocoupled relay so that voltage leaking from the input terminal of the optocoupled increases the voltage across the capacitive network until the optocoupled relay switches.

12. The method as claimed in claim 11, wherein the capacitance of the capacitive network is selected according to a desirous timing period.

13. The method as claimed in claim 12, wherein a capacitance of approximately 10,000 μF is configured to provide a time period of approximately eight minutes.

14. The method as claimed in claim 12, further comprising the circuit as claimed in claim 2, the method comprising operating the reset switch to pull the rail to ground to reset the relay.

15. The method as claimed in claim 11, wherein the resistance of the circuit is selected according to a desirous timing period.
